(19) United States
(12) Patent Application Publication
(10) Pub. No.: US 2023/0359789 A1
(43) Pub. Date: Nov. 9, 2023

(54) VARYING EMBEDDING(S) AND/OR ACTION MODEL(S) UTILIZED IN AUTOMATIC GENERATION OF ACTION SET RESPONSIVE TO NATURAL LANGUAGE REQUEST

(71) Applicant: X Development LLC, Mountain View, CA (US)

(72) Inventors: David Andre, San Francisco, CA (US); Rishabh Singh, San Jose, CA (US); Rebecca Radkoff, San Francisco, CA (US); Yu-Ann Madan, San Francisco, CA (US); Nisarg Vyas, Ahmedabad (IN); Jayendra Parmar, Mahesana (IN); Falak Shah, Ahmedabad (IN); Shaili Trivedi, Mountain View, CA (US)

(21) Appl. No.: 18/142,472

(22) Filed: May 2, 2023

Related U.S. Application Data
(60) Provisional application No. 63/338,313, filed on May 4, 2022.

(51) Int. Cl. G06F 30/27; G10L 15/183

(52) U.S. Cl. CPC G06F 30/27; G10L 15/183

(57) ABSTRACT

As opposed to a rigid approach, implementations disclosed herein utilize a flexible approach in automatically determining an action set to utilize in attempting performance of a task that is requested by natural language input of a user. The approach is flexible at least in that embedding technique(s) and/or action model(s), that are utilized in generating action set(s) from which the action set to utilize is determined, are at least selectively varied. Put another way, implementations leverage a framework via which different embedding technique(s) and/or different action model(s) can at least selectively be utilized in generating different candidate action sets for given NL input of a user. Further, one of those action sets can be selected for actual use in attempting real-world performance of a given task reflected by the given NL input. The selection can be based on a suitability metric for the selected action set and/or other considerations.

### BACKGROUND

Various model-based (e.g., machine learning model-based) techniques have been proposed for automatically generating actions that can be implemented in attempting performance of a task. However, such techniques can be rigid in that the same model is always utilized in generating actions and/or in that input(s), processed utilizing the model in generating the actions, are always generated in the same manner. As a result, such techniques can lack robustness in many situations, resulting in actions that fail in successful performance of the task in those situations. Such techniques can additionally and/or alternatively implement generated actions without first considering whether the actions are suitable to perform the task and/or are more suitable than alternative actions. This can result in implementation of actions that fail in successful performance of the task in many situations.

### SUMMARY

Implementations described herein relate to methods and apparatus for robust automatic generation of an action set, for use in performing a task, in response to free form natural language (NL) input (e.g., a spoken utterance) that is provided by a user and that requests performance of the task. The generated action set can be provided for use in performing the task. For example, providing the generated action set can cause the action set to be implemented automatically, thereby causing automatic performance of the task.

Action sets can be generated for various tasks across various domains utilizing techniques disclosed herein. Some non-limiting examples of tasks include: automatically controlling a computer application; automatically monitoring a video feed for occurrence of certain condition(s) and automatically performing action(s) in response; automatically transforming source code in a first programming language to source code in a second programming language; automatically generating an application programming interface (API); and/or automatically monitoring changes to inventory database(s) and automatically performing action(s) in response; and/or automatically integrating with a new replacement subsystem via automatically adapting to its API (e.g., automatically integrating with a new web application framework (e.g., a TypeScript based framework) when switching from a former web application framework (e.g., a JavaScript based framework))

As opposed to a rigid approach, implementations disclosed herein utilize a flexible approach in automatically determining an action set to utilize in attempting performance of a task that is requested by NL input of a user. The approach is flexible at least in that embedding technique(s) and/or action model(s), that are utilized in generating action set(s) from which the action set to utilize is determined, are at least selectively varied. Put another way, implementations leverage a framework via which different embedding technique(s) and/or different action model(s) can at least selectively be utilized in generating different candidate action sets for a given NL input of a user. Further, one of those action sets can be selected for actual use in attempting real-world performance of a given task reflected by the given NL input. The selection can be based on a suitability metric for the selected action set and/or other considerations. For instance, the selection can be based on the suitability metric satisfying an absolute threshold or a threshold relative to suitability metric(s) for alternative action set(s). Such a flexible approach is more robust, enabling determinations of corresponding action sets that are successful for a wide variety of corresponding NL inputs and/or for a wide variety of corresponding states of a domain.

Notably, which embedding technique(s) and/or action model(s) are utilized to generate an action that is selected, for a corresponding NL input and corresponding state of a domain, will vary for differing NL inputs and/or for differing states of a domain. As a particular example, for a first NL request and for a first state of a domain, a determined action set for utilization can be one that is generated based on processing embedding(s), generated using first technique(s), using a particular action model. On the other hand, for a second NL request and/or for a second state of the domain, a determined action set for utilization can be one that is generated based on processing alternate embedding(s), generated using second technique(s), using the particular action model. As another particular example, for a first NL request for a first state of a domain, a determined action set for utilization can be one that is generated based on processing embedding(s), generated using first technique(s), using a first action model. On the other hand, for a second NL request and/or for a second state of the domain, a determined action set for utilization can be one that is generated based on processing embedding(s), generated using the first technique(s), using an alternate action model.

Implementations disclosed herein additionally or alternatively at least selectively simulate implementation of generated action set(s) in determining an action set to utilize in attempting performance of a task. As described herein, such simulation(s) can help ensure, prior to real-world implementation of a determined action set, that the determined action set is suitable for performing the task, thereby increasing accuracy of determined action sets. Such simulation(s) can additionally or alternatively be utilized to determine whether additional action set(s) should be generated utilizing alternative embedding technique(s) and/or alternative action model(s) and/or can help guide the generation of the additional action set(s). In these and other manners, simulations can be utilized to determine whether and/or how to generate additional action set(s) for consideration, balancing the desire for robustness and accuracy with the desire for efficient utilization of computational resources in generating and/or evaluating additional action set(s).

As a non-limiting working example of implementations disclosed herein, assume that a computer aided design (CAD) application is executing on a client device and is displaying a “widget” (among other things), and that a user provides NL input that is a spoken utterance of “make the widget 10% larger”. In this working example, the domain for the task can be the particular CAD application, a class of applications (e.g., any CAD application or, more generally any visual manipulation application), or other domain. Further, the task of the working example relates to control of a computer application. However, as referenced above and elsewhere herein, techniques disclosed herein can be utilized in generating and/or evaluating action sets for various tasks across various domains utilizing techniques disclosed herein. In some implementations or for some domains, the same embedding technique(s) and/or action model(s) can be considered for each of multiple domains. In other implementations or for some other domains, the collection of embedding technique(s) and/or action model(s) considered for those domains can each be specific to the domain.

Continuing with the working example, a first request embedding can be generated using a first embedding technique that generates the request embedding based on NL input data that directly reflects the NL input. For example, the NL input data can include text of the NL input (e.g., text generated by automatic speech recognition of the spoken utterance). Using the first technique, the text can be processed using a large language model (LLM), or other machine learning (ML) model, to generate an NL embedding that is a lower dimensional semantic representation of the NL input data. The first request embedding can conform to the NL embedding. The LLM model, or other machine learning model used in generating the NL embedding, can optionally be specific to the domain.

A second request embedding can also be generated, using a second embedding technique, that generates the request embedding based on alternate NL input data that is generated by modifying and/or supplementing the NL input data based on domain specific knowledge (DSK). For example, the NL input can be modified and/or supplemented, based on the DSK, prior to processing of the NL input by the LLM model (i.e., the modified and/or supplemented NL input would be processed). For instance, a term in the NL input can be replaced by, or supplemented with, a domain specific definition for that term.

A third request embedding can also be generated, using a third embedding technique, that separately processes DSK, that relates to term(s) of the NL input, using the LLM model or a separate machine learning model, to generate a DSK embedding. That DSK embedding can then be concatenated or otherwise combined with an NL input embedding generated based on processing the NL input data—and the combined embedding used as the request embedding. For example, the DSK embedding and the NL input embedding can be processed together, over an additional neural network, to generate a combined lower-dimensional embedding. As one particular instance, domain specific definition(s) for term(s) of the NL input can be separately processed to generate the domain specific knowledge embedding (e.g., a definition for “widget” that is specific to the domain). As another particular instance, domain specific image(s) for term(s) of the NL input can be separately processed to generate the domain specific knowledge embedding (e.g., a picture of a “wicket” that is specific to the domain).

A fourth request embedding can also be generated, using a fourth embedding technique, that generates the request embedding based on further alternate NL input data that is generated by modifying and/or supplementing the NL input data based on external, not domain specific, knowledge. For example, a general web search can be performed, based on some or all of the NL input data, and text from responsive result(s) (e.g., the top result) can be utilized to supplement or replace term(s) in the NL input data. For instance, a general web search for “widget” can be performed, and a snippet of text from the top result utilized to modify and/or supplement the NL input data. As another example, a nearest-neighbor search can additionally or alternatively be performed and result(s) from the nearest-neighbor search additionally or alternatively utilized to modify and/or supplement the NL input data. The nearest-neighbor search can be performed based on the NL input data and across at least one large text corpus, to identify text (e.g., text from nearest-neighbor(s) to all or part(s) of the NL input data), and that identified text used to modify and/or supplement the NL input data.

The first request embedding can be processed, using an action model, to generate a first candidate action set. The second request embedding can be processed, using the action model, to generate a second candidate action set. The third request embedding can be processed, using the action model, to generate a third candidate action set. The fourth request embedding can be processed, using the action model, to generate a fourth candidate action set. Each of the first, second, third, and fourth action sets include respective actions that can potentially be used, alone or in combination with other action(s), to control the application in accordance with the request of the NL input. The first, second, third, and fourth action sets can include differing actions and/or differing orders of actions based on, for example, each being generated using different request embeddings.

Each action of the first, second, third, and fourth action sets is implementable through interaction with the application and, when implemented, can result in generated output (e.g., that is usable by another action) and/or can result in some control of the application. The control of the application can be through emulated input(s) (e.g., emulated touch input(s)) and/or via an API of the application. The actions can each include corresponding program code, such as code in JavaScript, Python, C++, or other programming language and/or can include API call(s).

Some actions can be atomic or granular. One example of such an atomic action is “select object of class <X>”, where “X” is a variable that can be populated based on term(s) of the NL input. Another example of an atomic action is “identify target location with <Y>property/properties”, where Y is a variable that can be populated based on term(s) of the NL input. Yet another example of an atomic action is “drag selected object to <target location>”, where <target location> is a variable that can be populated based on the output of the atomic action of “identify target location with <Y>property/properties”. Further examples of atomic actions include “click rotate right 90 degrees button”, “select all”, and “delete”—each of which do not include any variables. Such action(s) that do not include any variables are also referenced herein as state-independent actions. That is, state-independent actions will be executed in the same manner regardless of the corresponding state of the domain. For example, a “click rotate right 90 degrees button” will result in that button being “clicked” without regard to what else is being rendered in the CAD application. In contrast, some action(s) that include variable(s) that are dependent on the state, are also referenced herein as state-dependent actions. Put another way, they can be state-dependent in that they are implemented in dependence on the current state, resulting in differing action(s) for differing state(s). For example, with the “select object of class <X>” example, which object is selected will be dependent on “class <X>” and will be dependent on the state of the CAD application. For instance, if “class <X>” is “red” and there is a red circle at the top of an active screen of the CAD application, implementation of the state-dependent action will result in the red circle being selected. In contrast, if there is instead a red square at the bottom of the active screen, implementation of that state-dependent action will result in the red square being selected. As another example, for a “count the objects of class <X>” state-dependent action, the result of implementation of the state-dependent action will depend on how many objects, of “class <X>”, are present in the state. As described herein, atomic actions can be composed together into an action set, and the application can be controlled based on the action set. Some actions can optionally include more coarse pre-composed sets of multiple atomic actions such as “select all and click rotate right 90 degrees button”. An action set can also be composed of one or more “more coarse” actions, optionally along with atomic action(s).

In some implementations, additional and/or alternative action set(s) can additionally or alternatively be generated using alternative action model(s). For example, the first request embedding can be processed, using an alternative action model, to generate a fifth action set. As another example, the second request embedding can be processed, using the alternative action model, to generate a sixth action set. The alternative action model can be of a different type and/or trained in a different manner. For example, the action model can be a model that is used to generate a probability distribution over coarse and/or granular actions based on processing the request embedding and an embedding of a current state of the domain. Candidate action set(s) can then be generated by composing the highest probability action(s) as indicated by the generated probability distribution. For example, the action model can generate a probability distribution over 100 candidate actions, A1-A100. A first composed action set can be an ordered sequence of the four highest probability actions such as {A1, A25, A77, A42}, a second candidate set can be an alternate ordered sequence of those four highest probability actions such as {A1, A77, A25, A42}, and a third candidate set can be an ordered sequence of five actions sampled from the ten highest probability actions such as {A1, A25, A82, A29, A42}. As another example, the alternative action model can be an RL policy model that is used by an RL agent to iteratively process a sequence of states of the domain and generate a next action based on the processing. The RL agent can then implement the next action, resulting in a next corresponding state in the sequence. Accordingly, in this other example, the action set can be the sequence of actions that are generated by the RL agent in the iterative processing (i.e., a corresponding action generated at each iteration).

Each of the generated action sets can be evaluated to determine suitability of the action set, and the action set that is most suitable (and optionally satisfies a suitability threshold), selected for actual real-world implementation. In some implementations, evaluation of an action set can include eliminating an action set if it violates one or more action rules defined for a domain. For example, for a domain, a given action rule can define that a given action is not allowed at all or is not allowed if it occurs before or following certain other action(s). If an action set includes the given action or includes the given action before or following certain other action(s), that action set can violate the given action rule and be eliminated.

In some implementations, evaluation of an action set can additionally or alternatively include determining suitability of the action set based on performing a simulation based on that action set. The simulation of an action set can be performed in a simulated environment that reflects a corresponding state of the domain. For example, the initial simulated environment can reflect the CAD application in its current state. Some action sets can be generated in advance of the simulation, and implemented during a corresponding simulation. Other action sets may be generated during a corresponding simulation. For example, action sets generated using an RL agent and an RL policy model, can be generated during a corresponding simulation based on processing simulated state data from the simulation. As described herein, some or all actions, of an action set, can be state-dependent, meaning that their implementation will be dependent on the initial simulated environment and on modifications to that simulated environment, through any implementation(s) or preceding action(s) of the action set.

In some implementations, determining suitability of the action set based on the simulation of that action set can include determining whether the simulation violated one or more state rules defined for a domain. For example, a state rule for a domain can define that a certain state should never be encountered for the domain. If simulation data, from the simulation, indicates the certain state was encountered, then the action set can be determined to be unsuitable or a suitability metric, for the action set, can be negatively impacted.

In some implementations, determining suitability of the action set based on the simulation of that action set can additionally or alternatively include causing simulation data, from the simulation, to be rendered to a user that provided the NL request, and determining suitability based on feedback from the user in response to the rendering. For example, a screenshot of the simulated environment in its final state from a simulation, or other data that reflects the final state from the simulation, can be presented to the user and the user can provide user interface input(s) that reflect whether the screenshot reflects successful performance of the task. Instances of negative feedback can be used to eliminate a corresponding action set or to negatively impact a suitability metric for the corresponding action set. In contrast, instances of positive feedback can be used to select a corresponding action set as most suitable, or to positively impact a suitability metric for the corresponding action set.

In some implementations, determining suitability of the action set based on the simulation of that action set can additionally or alternatively be based on how closely the simulation conforms to the request of the NL input. As one example, a final state of the simulation can be processed to generate a NL description of the final state, and that NL description (e.g., an embedding thereof) compared to the NL input in generating a suitability metric. For example, “closer” embeddings can correspond to better suitability metrics, which indicate more suitability. For instance, a screenshot of the simulated final state can be processed using an image captioning model to generate the NL description. As another example, a video (e.g., series of screenshots) from the simulation can be processed to generate a NL description of the simulation, and that NL description compared to the NL input in generating the suitability metric. For example, each of the screenshots can be individually processed using a first machine learning model to generate a corresponding embedding, and the embeddings processed in a temporal sequence (e.g., the embeddings corresponding to the earliest in time screenshot processed first) using a second machine learning model (e.g., a transformer) to generate a NL description of the simulation and/or to generate an overall embedding that is semantically descriptive of the simulation. As another example, non-visual (i.e., not an image and not a video) simulation data from the simulation can be processed to generate a NL description of the simulation, such as audio data from the simulation (e.g., generated by the simulated application during the simulation), text data from the simulation (e.g., generated by the simulated application during the simulation), and/or other data from the simulation. More generally, one or more instances of simulation data, that each reflects a corresponding state of the simulated application at a corresponding time instance, can be processed to generate one or more corresponding embeddings and/or other representation(s). Further, the generated embedding(s) and/or other representation(s) can be utilized in generating the suitability metric (e.g., by comparison to an NL input embedding and/or a request embedding).

In some implementations of the working example, the first, second, third, fourth, and/or additional action sets are generated in parallel. This can reduce latency in resolving an action set to utilize for real-world implementation. In other implementations, only a subset of the action sets (e.g., only the first action set) is generated initially and, only if the action set(s) of the subset are determined to be unsuitable, are additional action set(s) generated and evaluated. For example, only the first action set can be generated and evaluated initially and, only if the evaluation indicates unsuitability, will the second action set then be generated and/or evaluated. Further, only if the evaluation of the second action set indicates unsuitability, will the third action set then be generated and/or evaluated. This can conserve computational resources by reducing an amount of processing being performed at a given time and at least selectively obviating the need to generate and/or evaluate subsequent action set(s) (e.g., when an earlier generated action set is determined to be suitable).

In various implementations, determining whether to generate disparate action sets in parallel (or the degree of parallelization) can be dependent on one or more factors. For example, the domain of the request or the request itself can indicate whether the request is urgent (in which some degree of parallel will be utilized) or not (in which case no parallel processing or a lesser degree of parallel processing will be utilized). As another example, determining whether to generate disparate action sets in parallel can additionally or alternatively be based on the current load on server(s) performing action set generation and/or simulation.

The preceding is provided as a non-limiting overview of some implementations disclosed herein. These and other implementations are described in further detail herein.

In addition, some implementations include one or more processors of one or more computing devices, where the one or more processors are operable to execute instructions stored in associated memory, and where the instructions are configured to cause performance of any of the aforementioned methods. Some implementations include at least one non-transitory computer readable storage medium storing computer instructions executable by one or more processors to perform any of the aforementioned methods.

### BRIEF DESCRIPTION OF THE DRAWINGS

FIG. 1 is a diagram of an example environment in which implementations disclosed herein can be implemented.

FIG. 2 schematically illustrates an example of how components of FIG. 1 can interact in automatically determining an action set to utilize in attempting performance of a task that is requested by NL input of a user.

FIG. 3 is a flowchart illustrating an example method of practicing selected aspects of the present disclosure, according to implementations disclosed herein.

FIG. 4 is a flowchart illustrating another example method of practicing selected aspects of the present disclosure, according to implementations disclosed herein.

FIG. 5 illustrates an example architecture of a computing device.

### DETAILED DESCRIPTION

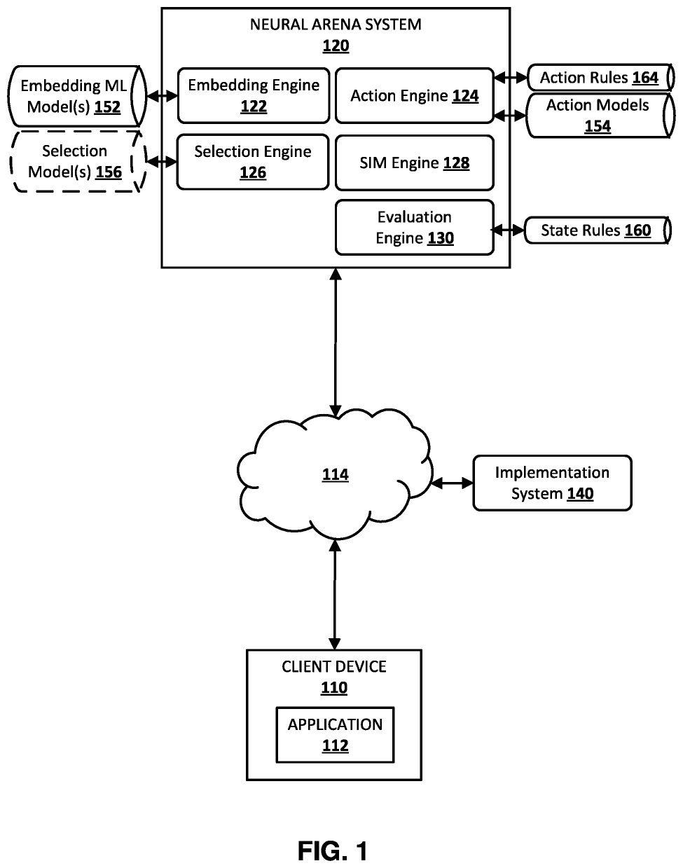

FIG. 1 schematically depicts an example environment in which selected aspects of the present disclosure can be implemented, in accordance with various implementations. Any computing devices depicted in FIG. 1 or elsewhere in the figures can include logic such as one or more microprocessors (e.g., central processing units or “CPUs”, graphical processing units or “GPUs”, tensor processing units or (“TPUs”)) that execute computer-readable instructions stored in memory, or other types of logic such as application-specific integrated circuits (“ASIC”), field-programmable gate arrays (“FPGA”), and so forth. Some of the systems depicted in FIG. 1, such as neural arena system 120, can be implemented, in whole or in part, using one or more server computing devices that form what is sometimes referred to as a “cloud infrastructure,” although this is not required.

The neural arena system 120 can be operably coupled with one or more client computing devices (also referred to herein as client(s)), such as client computing device 110, via one or more computer networks 114. The neural arena system 120 can automatically determine, based on NL input provided by a user of client 110, an action set to utilize in attempting performance of a task that is requested in the NL input. For example, the user can provide, via microphone(s) of the client 110, free form spoken NL input that reflects a task to be performed within a domain, and the neural arena system 120 can automatically determine, based on the NL input, an action set to utilize in attempting real-world performance of the task. Further, the neural arena system 120 can be operably coupled with an implementation system 140 via the network(s) 114.

The implementation system 140 can implement an action set, determined by the neural arena system 120, in a corresponding domain in attempting real-world performance of a corresponding task. For example, if the task is automatically monitoring a video feed for occurrence of certain condition(s), the implementation system 140 can process the video feed, using the action set, in monitoring for occurrence of the certain condition(s) and, optionally, generate alert(s) in response to detection of any of the certain condition(s) using the determined action set. In such an example, the implementation system 140 can be implemented in, for example, server(s) that receive the video feed as a stream over the Internet and/or in computing device(s) that are on a local network with the camera providing the video feed and receive the video feed as a stream of the local network. As another example, if the task is automatically transforming source code in a first programming language to source code in a second programming language, the implementation system 140 can be implemented in server(s) and/or client device(s), can receive first programming language source code, and can automatically transform it to second programming language source code using the determined action set.

The client device 110 can include one or more applications, such as application 112, that interact with the neural arena system 120. For example, the application 112 can be one via which NL inputs of a user can be provided (e.g., through spoken and/or typed input(s)) and the application 112 can transmit the NL inputs to the neural arena system 120. Also, for example, the application 112 can be one via which output(s) generated by the neural arena system 120 can be rendered to the user, such as output(s) requesting user feedback (e.g., output(s) that reflect a final state of a simulation of a candidate action set) and/or output(s) that reflect an action set determined by the neural arena system 120 (e.g., for confirmation of the action set prior to automatic real-world implementation). In some implementations, where the task includes control of a computer application executing on the client 110, the application 112 (or another application) can be one that can be controlled using an action set determined by the neural arena system 120. In those implementations, the implementation system 140 can interface with the application in implementing the action set and/or can be integrated (in whole or in part) as part of the application.

Although neural arena system 120 and implementation system 140 are depicted in FIG. 1 as separate from one another and as connected to the client 110 via the network(s) 114, in various implementations one or more aspects of neural arena system 120 and implementation system 140 can be combined and/or can be implemented locally at the client 110. For example, one or more of the engines of neural arena system 120 can be implemented at the client 110 and/or one or more aspects of the implementation system 140 can be implemented at the client 110.

In various implementations, neural arena system 120 includes an embedding engine 122, an action engine 124, a selection engine 126, a simulation (SIM) engine 128, and/or an evaluation engine 130.

The embedding engine 122 can interface with one or more embedding ML models 152 in generating embeddings described herein. Which embedding ML model(s) 152 the embedding engine 122 interfaces with, and/or the data it processes in interfacing with one or more of the embedding ML model(s) 152, can be dependent on the embedding technique(s) that are being utilized by the embedding engine 122. For example, for a given NL input the embedding engine 122 can, in one instance, generate a first embedding based on a first embedding technique that is processing NL input data, that reflects the NL input, using a domain specific LLM model of the embedding models 152. Further, for the given NL input the embedding engine 122 can, in another instance, generate a second embedding based on a second embedding technique that includes processing alternate NL input data using the domain specific LLM model. The embedding engine 122 can generate the alternate NL input data by modifying and/or supplementing the NL input data using DSK. Yet further, for the given NL input the embedding engine 122 can, in another instance, generate a third embedding based on a third embedding technique that includes processing an image using an image embedding model of the embedding ML models 152. The image can be, for example, a DSK image related to the NL input data or an external image related to the NL input data.

The embedding technique(s) being utilized at a given instance by the embedding engine 122 can be dependent on various factors and, in some implementations, can be dictated by the selection engine 126. For example, the embedding technique(s) utilized can be dependent on a domain of the task, the NL input for which embedding(s) are being generated, and/or the action model(s) being utilized by the action engine 124 in generating candidate action set(s). Also, for example, the embedding technique(s) utilized in a given instance for an NL input can additionally or alternatively be based on embedding technique(s) utilized in prior instance(s) in generating candidate action set(s) for the NL input and/or evaluations(s) of those candidate action set(s). Various embedding ML models 152 can be provided. For example, embedding ML models 152 can include those that are specific to a particular domain, those that are specific to a set of particular domains, and/or those that are domain agnostic. As another example, embedding ML models 152 can additionally or alternatively include those specific to a first type of data (e.g., natural language data), those specific to a second type of data (e.g., images), and/or those specific to a third type of data (e.g., audio data).

The action engine 124 can interface with a plurality of action models 154 in generating candidate action sets described herein. In some implementations, the action engine 124 also interfaces with one or more action rules 164, which can be used to eliminate some generated candidate action set(s) from further consideration (e.g., from further consideration by the evaluation engine 130). The action rules 164 can be specific to a domain and/or specific to a corresponding requesting entity, such as a user providing a corresponding NL request or an organization associated with the user providing a corresponding NL request. For example, for a particular domain and a particular organization, a given action rule can define that a given action is not allowed at all or is not allowed if it occurs before or following certain other action(s).

Which action model(s) 154 the action engine 124 interfaces with at a given instance can be dependent on various factors and, in some implementations, can be dictated by the selection engine 126. For example, the action model(s) 154 utilized can be dependent on a domain of the task, the NL input for which embedding(s) are being generated, and/or the embedding(s) being generated by the embedding engine 122. Also, for example, the action model(s) 154 utilized in a given instance for an NL input can additionally or alternatively be based on action model(s) utilized in prior instance(s) in generating candidate action set(s) for the NL input and/or evaluations(s) of those candidate action set(s). Various action models 154 can be provided. For example, action models 152 can include machine learning models and/or heuristic models. As another example, action models 152 can include those that are specific to a particular domain, those that are specific to a set of particular domains, and/or those that are domain agnostic. As another example, action models 152 can include: those that represent an RL policy and are utilized to generate an action set by iteratively generating a corresponding next action of the action set based on applying updated state data at each iteration; those that are utilized to generate, in a single iteration, one or more candidate action sets; those that represent a value function and are utilized to generate a measure that reflects the value of an action set, current state pair; and/or other action model(s). For instance, action models can include one or more of an RL policy ML model, an action sequence ML model, a constraint satisfaction model, a SAT solver, and/or other model(s).

In some implementations, the selection engine 126 can interact with the embedding engine 122 in dictating which embedding technique is being utilized by embedding engine 122 at a given instance and/or can interact with the action engine 124 in dictating which action model(s) are being utilized by action engine 124 at a given instance. For example, the selection engine 126 can dictate that the embedding engine 122 utilize a first embedding technique initially. Then, only if evaluation engine 130 indicates that corresponding candidate action set(s) generated based on the first embedding technique are unsuitable, the selection engine 126 can dictate that the embedding engine 122 utilize a second embedding technique in generating additional candidate action set(s). As another example, the selection engine 126 can dictate that the embedding engine 122 utilize a first embedding technique and a second embedding technique initially. Then, only if evaluation engine 130 indicates that corresponding candidate action sets generated based on the first embedding technique and the second embedding technique are unsuitable, the selection engine 126 can dictate that the embedding engine 122 utilize a third and/or a fourth embedding technique in generating additional candidate action set(s).

In some implementations, the selection engine 126 can optionally utilize one or more selection models 156 in determining which embedding technique(s) and/or action(s) to utilize at a given instance. For example, selection model(s) 156 can include a selection ML model that can be used to process a domain of a task and/or NL input data that requests the task (e.g., an embedding of the NL input data) and to generate output that indicates a corresponding probability for each of a plurality of embedding technique(s) and/or action model(s). The selection engine 126 can utilize the generated output in selecting which embedding technique(s) and/or action model(s) to utilize. For example, the selection engine 126 can use the output to select a highest probability embedding technique and/or a highest probability action model for utilization initially. Such a selection ML model can be trained, for example, based on supervised training examples that are based on past NL inputs and action sets determined to be suitable (and optionally confirmed as suitable after real-world implementation thereof). For example, assume a given action set was generated for NL input using a first embedding technique and a first action model, and was determined to be suitable. In response, a training example can be generated that includes, as training example input, a domain of the task of the NL input and/or NL input data for the NL input and, as training example output, positive value(s) for the for the first embedding technique and the first action model, and negative values for all other embedding techniques and action models.

The SIM engine 128 can be used, for each of the action sets generated by action engine 124, to simulate implementation of the action set in a simulated environment, such as a simulated environment that reflects a current state of the domain. Further, the SIM engine 128 generates simulation data for each of the simulations. In some situations, an action set can be generated independent of its simulation, and the SIM engine 128 utilized to simulate the action set after the action set is generated. In some other situations, an action set can be generated during the simulation via the SIM engine 128. For example, some RL policy models can be utilized, in simulation, to generate a candidate action set and the candidate action set will be implemented during the simulation and its generation will be dependent on simulated states encountered during the simulation.

As one particular example, where the task is control of a computer application, the SIM engine 128 simulates performance of controlling the application 112 by implementing a candidate action set. In such an example, the SIM engine 128 can use an emulator in performing the simulations and can optionally start each of the simulations from a current state of the application. As another particular example, where the task is transforming code from a first programming language to a second programming language, the SIM engine 128 simulates performance of the transformation by implementing a candidate action set and, optionally, further simulates implementation of the resulting transformed second programming language code. As yet another particular example, where the task is automatically monitoring changes to inventory database(s) and automatically performing action(s) in response, the SIM engine 128 simulates dynamically changing inventory database(s) and simulates monitoring of the simulation database(s) by implementing a candidate action set. As yet a further particular example, where the task is automatically monitoring a video feed for occurrence of certain condition(s) and automatically performing action(s) in response, the SIM engine 128 simulates a video feed and/or replays a past real-world video feed and simulates monitoring of the video feed by implementing a candidate action set.

The evaluation engine 130 can determine whether a candidate action set is suitable for performing a corresponding task and/or determine, from amongst multiple candidate action sets, a most suitable of the candidate action sets. In various implementations, in evaluating an action set, the evaluation engine 130 utilizes simulation data from the simulation of the action set by SIM engine 128. In some of those implementations, the evaluation engine 130 can compare the simulation data to one or more state rules 160, which can be used to determine that a candidate action set is unsuitable and/or to negatively impact a suitability score, for the candidate action set, that is utilized in determining suitability of the candidate action set. The state rules 160 can be specific to a domain and/or specific to a corresponding requesting entity, such as a user providing a corresponding NL request or an organization associated with the user providing a corresponding NL request. For example, for a particular domain and a particular organization, a given state rule can define that a given state should never be encountered or that a particular sequence of states should never be encountered. If simulation data, from simulation of a candidate action set, indicates that the given state and/or the particular sequence of states was encountered, evaluation engine 130 can determine that candidate action set is unsuitable. As another example, for a particular domain and a particular organization, a given state rule can define that a given state or a particular sequence of states is undesirable, but not prohibited. If simulation data, from simulation of a candidate action set, indicates that the given state and/or the particular sequence of states was encountered, evaluation engine 130 can negatively impact a suitability metric for the candidate action set.

In some additional or alternative implementations of utilizing simulation data in evaluating an action set, evaluation engine 130 can additionally or alternatively solicit and utilize user feedback based on the simulation data and/or analyze how closely the simulation data conforms to the request of the corresponding NL input. For example, the evaluation engine 130 can cause simulation data, from the simulation, to be rendered to a user that provided the NL request, and determine suitability based on feedback from the user in response to the rendering. For example, the evaluation engine 130 can cause a screenshot of the simulated environment in its final state from a simulation to be rendered at the client 110 and, in response, the user can provide user interface input(s) that reflect whether the screenshot reflects successful performance of the task. The evaluation engine 130 can use instances of negative feedback to eliminate a corresponding action set or to negatively impact a suitability metric for the corresponding action set. In contrast, the evaluation engine 130 can use instances of positive feedback to select a corresponding action set as most suitable, or to positively impact a suitability metric for the corresponding action set.

In some additional or alternative implementations of utilizing simulation data in evaluating an action set, evaluation engine 130 can additionally or alternatively determine suitability of the action set based on how closely simulation data, from the simulation of that action set, conforms to the request of the NL input. As one example, evaluation engine 130 can process a final state of the simulation to generate a NL description of the final state, and compare that NL description to the NL input data in generating a suitability metric. For instance, an embedding of the NL description of the final state can be compared to an embedding that is based on the NL description data (e.g., based on only the NL description data or based on the NL description data supplemented or modified as described herein). Comparisons that indicate a greater degree of similarity (e.g., “closer” embeddings) can correspond to better suitability metrics, which indicate more suitability (i.e., result in better suitability scores). For instance, a screenshot of the simulated final state can be processed using an image captioning model to generate the NL description.

Machine learning models described herein can be of various architectures and trained in various manners. For example, one or more of the models can be a graph-based neural network (e.g., as a graph neural network (GNN), graph attention neural network (GANN), or graph convolutional neural network (GCN)), a sequence-to-sequence neural network such as a transformer, an encoder-decoder, or a recurrent neural network (“RNN”, e.g., long short-term memory, or “LSTM”, gate recurrent units, or “GRU”, etc.), a BERT (Bidirectional Encoder Representations from Transformers). Also, for example, reinforcement learning, supervised learning, and/or imitation learning can be utilized in training one or more of the machine learning models. Additional description of some implementations of various machine learning models is provided herein.

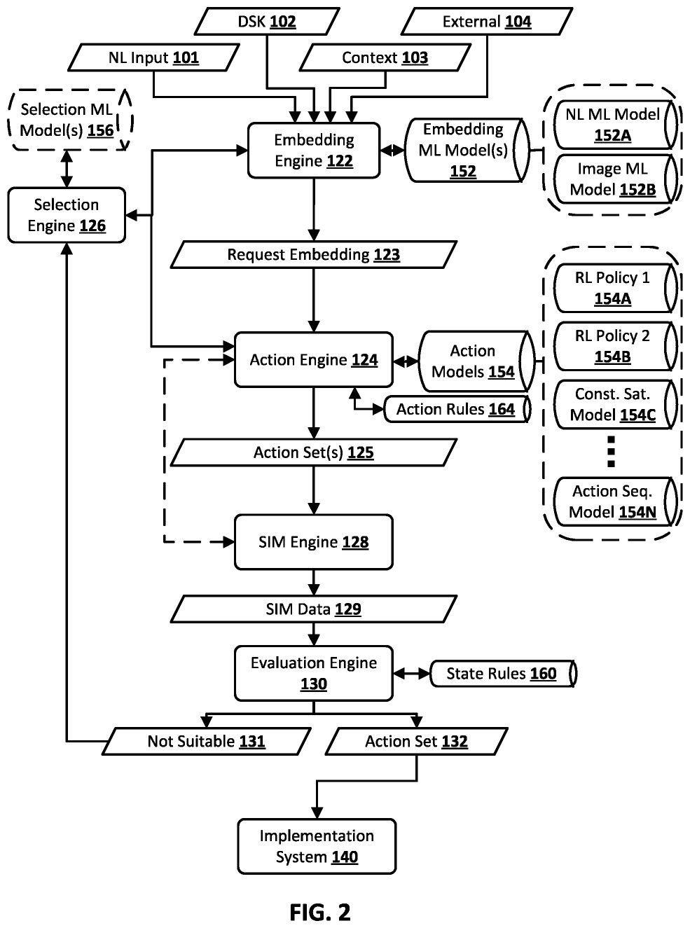

Turning to FIG. 2, description is provided of examples of: the engines 122, 124, 126, 128, and 130 of neural arena system 120; the interactions that can occur amongst those engines; and the models 152, 154, and 156 and the rules 160 and 164 that can be utilized by the neural arena system 120.

In FIG. 2, the embedding engine 122 processes at least NL input 101 in generating a request embedding 123. The NL input 101 is provided by a user, via interaction with user interface input device(s) of a client device (e.g., client 110 of FIG. 1), and the NL input 101 includes a request to generate actions for a task. For example, the NL input 101 can be spoken input, of the user, that is detected via microphone(s) of the client 110, and the embedding engine 122 can process recognized text, generated based on the spoken input (e.g., using automatic speech recognition (ASR)), in generating the request embedding 123. As another example, the NL input 101 can be typed input provided via a virtual or hardware keyboard of the client 110, and the typed text can be processed by the embedding engine 122 in generating the request embedding 123. For instance, the recognized text or typed text can be processed using an NL ML model 152A of request ML model(s) 152, to generate an NL embedding. The NL ML model 152A can be, for example, an LLM. The request embedding 123 can be the NL embedding or can be a function of the NL embedding and other NL embeddings.

In some implementations, the request engine 122 additionally utilizes domain specific knowledge (DSK) 102, context data 103, and/or external knowledge 104 in generating the request embedding 123. In those implementations, whether the DSK 102, the context data 103, and/or the external knowledge 104 is utilized is dependent on the embedding technique being utilized by embedding engine 122. Further, in some of those implementations, the embedding technique being utilized by the embedding engine 122 at a given instance can be dictated by the selection engine 126. For example, for an initial request embedding 123 for given NL input 101, the selection engine 126 can dictate that the request embedding 123 be generated using a first embedding technique in which only the NL input 101 is utilized in generating the request embedding 123. Further, for a next request embedding 123 for the same given NL input 101, the selection engine 126 can dictate that the request embedding 123 be generated using a second embedding technique in which the NL input 101 is utilized and DSK 102 is also utilized. For instance, the request engine 122 can use the DSK 102 to alter the NL input 101, and process the alteration of the NL input 101 using the NL ML model 152 to generate the request embedding 123. As a particular instance, the NL input 101 can be “make the wicket 15% smaller”, the request engine 122 can use the DSK 102 to find a domain specific definition for “wicket” of “small door beside a larger door”, and alter the NL input 101 to “make the small door 15% smaller” or to “make the wicket, the small door beside the larger door, 15% smaller”. Continuing with the particular instance, the request embedding can be the NL embedding, generated based on the alteration of the NL input 101. The selection engine 126 can, in dictating which embedding technique to utilize in a given instance, utilize the selection ML model(s) 156 and/or consider which embedding technique(s) have already been utilized for the given NL input 101.

As another example of an embedding technique that can be used by the embedding engine 122, the embedding engine 122 can identify, from DSK 102, particular domain specific knowledge that relates to term(s) of the NL input 101. Further, the embedding engine 122 can process the particular domain specific knowledge using one or more of the request ML model(s) 152 to generate DSK embedding(s). The embedding engine 122 can then concatenate or otherwise combine the DSK embedding(s) with the NL embedding and/or a context embedding (e.g., processed along with, over an additional neural network, to generate a lower-dimensional embedding)—and the combined embedding used as the request embedding 123. For example, the NL input 101 can be “make the wicket 15% smaller”, and the embedding engine 122 can generate an NL embedding based on the NL input 101 (unaltered). Further, the embedding engine 122 can identify, from DSK 102, a domain specific NL definition for “wicket” and/or can identify a domain specific image of a “wicket”. The embedding engine 122 can process the domain specific NL definition for “wicket”, using the NL ML model 152A to generate a domain specific NL definition embedding and/or can process the domain specific “wicket” image using the image ML model 152B to generate a domain specific image embedding. The embedding engine 122 can then generate the request embedding 123 as a function of the NL embedding and the domain specific NL definition embedding and/or the domain specific image embedding. The image ML model 152B can be, for example, a convolutional neural network (CNN) or other neural network trained to generate semantically rich embeddings of images based on processing of those images.

As referenced above, the embedding engine 122 can, for one or more embedding techniques, additionally or alternatively utilize context data 103 and/or external knowledge 104 in generating the request embedding 123. For example, the context data 103 can include current state data for the domain of the task, the embedding engine 122 can process the current state data to generate context embedding(s), and can generate the request embedding 123 as a function of the context embedding(s). For instance, the current state data can include an NL description of the current state of the domain. Additional or alternative context data 103 can be utilized in generating the context embedding(s), such as an indication of application(s) currently executing on a client device via which the NL input 101 was provided, recent NL input(s) provided via the client device, a current time of day or other current temporal data, a current location, and/or other context data. As another example, the external knowledge 104 can include data obtained via a general search engine or other general knowledge base and using the NL input 101. For example, the external knowledge 104 can include search result(s) returned from a general search engine responsive to a query that is formulated using the NL input 101. The embedding engine 122 can process the external knowledge 104 to generate knowledge embedding(s), and can generate the request embedding 123 as a function of the knowledge embedding(s). In some implementations, first context data can be utilized in a first embedding technique and distinct second context data can be utilized in a second embedding technique. For example, the first context data can include an indication of application(s) currently executing on a client device but exclude recent NL inputs and the second context data can include the recent NL inputs but exclude the indication of the application(s). As another example, the first context data can include a pixel-level abstraction (e.g., pixels themselves) of an image of the current state (e.g., a current state of an application) but exclude an indication of higher-level abstraction(s) of the image (e.g., shape(s) or other object(s) derived from the pixels)—and the second context data can include the higher-level abstraction(s) but exclude the pixel-level abstraction.

The action engine 124 processes the request embedding 123, using one or more of the action ML models, to generate one or more candidate action sets 125. For example, the action engine 124 can, in a given instance, process the request embedding using one of first RL policy model 154A, second RL policy model 154B, constraint satisfaction model 154C, action sequence model 154N, or other model(s) of action models 154 (e.g., other model(s) indicated by the vertical ellipsis in FIG. 2). In some of those implementations, which of the action model(s) 154 is utilized by the action engine 124 is at a given instance can be dictated by the selection engine 126. For example: for an initial instance for given NL input 101, the selection engine 126 can dictate that the candidate action set(s) 125 be generated using the first RL policy model 154A; for a second instance for the same given NL input 101, the selection engine 126 can dictate that the candidate action set(s) 125 be generated using the second RL policy model 154B; and for a third instance for the same given NL input 101, the selection engine 126 can dictate that the candidate action set(s) 125 be generated using the action sequence model 154N. Optionally, in generating the candidate action set(s) 125, the action engine 124 can eliminate one or more generated action set(s) based on those action set(s) violating action rule(s) 164 as described herein.

The SIM engine 128 can be used, for each of the candidate action set(s) 125, to simulate implementation of the action set in a simulated environment, such as a simulated environment that reflects a current state of the domain. Further, the SIM engine 128 generates simulation data 129 for each of the simulations. In some situations, an action set of the action sets 125 can be generated independent of its simulation, and the SIM engine 128 utilized to simulate the action set after the action set is generated. In some other situations, an action set can be generated by action engine 124 during the simulation via the SIM engine 128. This is reflected by the dashed double arrowed line between the action engine 124 and the SIM engine 128.

The simulation data 129 is provided to the evaluation engine 130. The evaluation engine 130 can determine, using the simulation data 129, whether a corresponding candidate action set, of the candidate action set(s) 125, is suitable for performing a corresponding task and/or determine, from amongst multiple candidate action sets, a most suitable of the candidate action sets. In some of those implementations, the evaluation engine 130 can compare the simulation data to one or more state rules 160, which can be used to determine that a candidate action set is unsuitable and/or to negatively impact a suitability score, for the candidate action set, that is utilized in determining suitability of the candidate action set. In some additional or alternative implementations of utilizing the simulation data 129 in evaluating an action set, evaluation engine 130 can additionally or alternatively solicit and utilize user feedback based on the simulation data 129 and/or analyze how closely the simulation data 129 conforms to the request of the NL input 101. In some additional or alternative implementations of utilizing the simulation data 129 in evaluating an action set, evaluation engine 130 can additionally or alternatively determine suitability of the action set based on how closely the simulation data 129, from the simulation of that action set, conforms to the request of the NL input 101.

If the evaluation engine 130 determines that none of the candidate action set(s) 125 is suitable, it can output a not suitable indication 131 to the selection engine 126. In response, the selection engine 126 can adapt the embedding technique utilized by the embedding engine 122 and/or the action model(s) 154 being utilized by the action engine 124. Further candidate action set(s) 125 can then be generated based on a different request embedding 123 (e.g., generated using an alternate embedding technique) and/or based on a different action model of the action model(s) 154. For example, the selection engine 126 can adapt the embedding technique being utilized, but not adapt the action model(s) 154 being utilized. In response, the embedding engine 122 can generate a different request embedding 123 using the different adapted embedding technique, and the action engine 124 will process the different request embedding 123 utilizing the same action model as before. This can result in generating different candidate action set(s) 125 due to the different request embedding 123. The different action set(s) 125 can be simulated by SIM engine 128 and resulting simulation data 129 utilized by evaluation engine 130 in evaluating the different candidate action set(s) 125. Multiple iterations of this can occur until, for example, the evaluation engine 130 determines an evaluated candidate action set is suitable.

If the evaluation engine 130 determines, in a given iteration, that one of the candidate action set(s) 125 is suitable, it can provide that action set 132 to the implementation system 140. The implementation system 140 can then cause the action set 132 to be implemented in a real-world environment. For example, the implementation system 140 can implement the action set 132 automatically and without first prompting the user for verification. As another example, the implementation system 140 can first prompt the user for verification before implementing, and only implement the action set 132 if affirmative user input is received in response to the prompt.

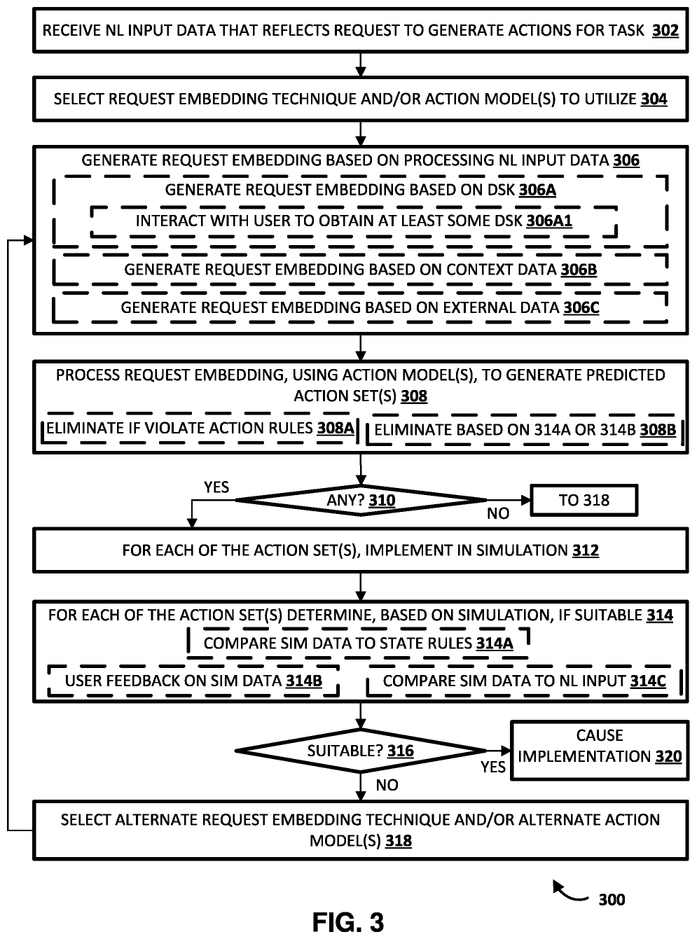

FIG. 3 is a flowchart illustrating an example method 300 for practicing selected aspects of the present disclosure, according to implementations disclosed herein. For convenience, the operations of the flow chart are described with reference to a system that performs the operations. This system may include various components of various computer systems, such as one or more components of neural arena system 120. Moreover, while operations of method 300 are shown in a particular order, this is not meant to be limiting. One or more operations may be reordered, omitted or added.

At block 302, the system receives NL input data that reflects a request to automatically generate actions for a task. For example, the request can be a spoken request, and the NL input data can be a transcription thereof that is generated using automatic speech recognition.

At block 304, the system selects a request embedding technique and/or action model(s) to utilize. In some implementations, the system selects the request embedding technique and/or the action model(s) to utilize based on a domain of the task and/or based on the NL input data of block 302. For example, the system can use defined heuristics that indicate, for a particular domain and/or for NL input data that includes particular term(s), a first embedding technique and a first action model should be utilized initially. As another example, the system can process the NL input data (e.g., an embedding thereof) and/or an indication of the domain, using a trained selection model (e.g., one of the selection model(s) 156 of FIG. 1), to generate output that indicates which embedding technique and/or action model(s) should be utilized. The system can select, based on the output, the embedding technique and/or the action model(s) to utilize initially.

At block 306, the system generates a request embedding based on processing the NL input data using an embedding ML model. In some implementations, the embedding ML model is selected, from multiple candidate embedding ML models, in accordance with the currently selected embedding technique. In some implementations or iterations, block 306 includes sub-block 306A, sub-block 306B, and/or sub-block 306C. In some of those implementations, which, if any, of the sub-block(s) are performed in a given iteration of block 306 can be dependent on the currently selected embedding technique. For example, for a first embedding technique none of the sub-block(s) can be performed, for a second embedding technique only sub-block 306A can be performed, for a third embedding technique only sub-block 306B can be performed, for a fourth embedding technique only sub-block 306C can be performed, for a fifth embedding technique only sub-blocks 306A and 306B can be performed, and/or for a sixth embedding technique all of sub-blocks 306A, 306B, and 306C can be performed.

At sub-block 306A, the system generates the request embedding based on DSK, such as pre-stored DSK. For example, the system can alter the NL input, with DSK, and generate the request embedding based on processing the altered NL input. As another example, the system can separately process DSK that is relevant to the NL input to generate domain specific embedding(s), and generate the request embedding as a function of an NL embedding from processing the NL input and as a function of the domain specific embedding(s).

Sub-block 306A optionally includes further sub-block 306A1, where the system interacts with the user to obtain at least some DSK. For example, the system can interact with the user to obtain at least some DSK in response to determining that there is no pre-stored DSK corresponding to one or more terms of the received NL input. In some implementations, performance of sub-block 306A without performance of sub-block 306A1 can be considered a first embedding technique and performance of sub-block 306A with performance of sub-block 306A1 can be considered a distinct second embedding technique.

At sub-block 306B, the system generates the request embedding based on context data, such as context data that describes a context of the NL input, but is not reflected by the content of the NL input itself. For example, the context data can include temporal context data (e.g., a time of day, a day of the week, and/or a day of the year), prior NL input context data (e.g., NL input(s) provided by the same user within the last N seconds and/or the last N NL input(s)), client context data (e.g., image(s) being rendered on a client at or near a time the NL input was provided at the client and/or application(s) being executed on a client at or near a time the NL input was provided). In some implementations, at block 306B, the system can process the context data to generate context embedding(s), and generate the request embedding as a function of an NL embedding from processing the NL input and as a function of the context embedding(s).

At sub-block 306C, the system generates the request embedding based on external data from external knowledge source(s). For example, a general web search can be performed, based on some or all of the NL input data, text from responsive result(s) (e.g., the top result) can be utilized to supplement or replace term(s) in the NL input data, and the system can generate the request embedding based on processing the altered NL input. As another example, the system can separately process text from the responsive result(s) to generate external data embedding(s), and generate the request embedding as a function of an NL embedding from processing the NL input and as a function of the external embedding(s). As yet another example, an image search can be performed, based on some or all of the NL input data, image(s) from responsive result(s) (e.g., the top images result) can be can be processed, using an image embedding ML model, to generate an image embedding, and the request embedding can be generated as a function of the image embedding and as a function of an NL embedding from processing the NL input (e.g., an NL embedding generated using a domain specific LLM).

At block 308, the system processes the generated request embedding, from the most recent iteration of block 306, using action model(s), to generate one or more predicted action set(s). For example, the system can process the generated request embedding, using an action model, to generate a single candidate action set or to generate multiple candidate action sets. In some implementations, the action model(s) utilized are selected, from multiple candidate action models, in accordance with the currently selected action model(s).

In some implementations, block 308 includes sub-block 308A and/or sub-block 308B.

At sub-block 308A, the system can eliminate one or more of the candidate action set(s), if the candidate action set(s) are determined to violate one or more defined action rules.

At sub-block 308B, the system can eliminate one or more of the candidate action set(s) based on prior iteration(s) of sub-blocks 314A and/or 314B (described below) for the NL input. Generally, sub-blocks 314A and/or 314B can also be utilized to eliminate candidate action set(s), but will eliminate a candidate action set based on the candidate action set producing an undesirable simulated state when implemented. In some situations, the action(s), of the action set, that resulted in that simulated state can be identified in sub-blocks 314A and/or 314B. In some of those implementations, sub-block 308B can include eliminating candidate action set(s) that include those action(s). For example, a candidate action set can be eliminated if it includes a particular action identified in sub-blocks 314A and/or 314B or if it includes a particular sequence of actions identified in sub-blocks 314A and/or 314B.

Additional and/or alternative techniques can be utilized to eliminate action set(s) at block 308. For example, when an ML model is utilized to generate an action set and a probability or other measure that indicates likelihood that action set is appropriate for the request embedding, implementations can eliminate action set(s) whose measure fails to satisfy a threshold.

At block 310, the system determines if there are any candidate action set(s) remaining from a most recent iteration of block 308. If not, the system proceeds to block 318 (described below). If so, the system proceeds to block 312.

At block 312, the system, for each of the action sets generated at the most recent iteration of block 308 (and not eliminated at block 308), implements the action set in simulation. As described herein, for some action model(s), the system can perform blocks 308 and 310 simultaneously. That is, for those action model(s), the system generates the actions of an action set sequentially through interaction with a simulated environment in simulation. For example, an RL agent can utilize an RL policy model, of the action model(s), in selecting and implementing actions of an action set in simulation. For other action model(s), the system can generate a completion action set in block 308 in advance of implementing that action set in simulation at block 310.

At block 314, the system determines, for each of the simulated action set(s) and based on the simulation, if the action set is suitable. The system determines whether the action set is suitable based on simulation data from the simulation. For example, the system can generate a suitability metric for an action set based on the simulation data, and determine, based on the suitability metric, whether the action set is suitable. For instance, if the suitability metric for an action set satisfies a threshold and indicates more suitability than any other action set(s) being considered at the iteration of block 314, then the action set can be determined to be suitable. Otherwise, the action set can be determined to be not suitable.

In some implementations, in determining whether an action set is suitable, block 314 includes sub-block 314A, sub-block 314B, and/or sub-block 314C.

At sub-block 314A, the system compares the simulation data, for the action set, to one or more state rules. For example, a state rule for a domain can define that a certain state should never be encountered for the domain. If simulation data, from the simulation, indicates the certain state was encountered, then the system can determine the action set is unsuitable. As another example, an additional or alternative state rule can define that an additional certain state is undesirable for the domain. If simulation data, from the simulation, indicates the certain state was encountered, then the system can negatively influence a suitability metric for the action set. The simulation data that is compared can include, for example, simulated state data that reflects a final simulated state and/or one or more intermediary simulated state(s).

At sub-block 314B, the system solicits user feedback on simulation data, and determines whether the action set is suitable based at least in part on user feedback received responsive to the solicitation. For example, the system can cause representation(s) of a final simulated state and/or intermediate simulated state(s) to be rendered (e.g., visually and/or audibly) to the user. The representations can be from, or generated from, the simulation data. Further, the system can process feedback, received via one or more user interface input(s) that are responsive to the rendering, and determine whether the action set is suitable based on the feedback. For example, instances of negative feedback can be used to eliminate a corresponding action set or to negatively impact a suitability metric for the corresponding action set. In contrast, instances of positive feedback can be used to select a corresponding action set as most suitable, or to positively impact a suitability metric for the corresponding action set.

At sub-block 314C, the system compares simulation data to the NL input data of block 302, and determines whether the action set is suitable based at least in part on the comparison. For example, comparisons that indicate at least a positive threshold degree of similarity can positively impact a suitability metric, which comparisons that indicate less than a negative threshold degree of similarity can negatively impact a suitability metric. As a particular example, the system can process a final state of the simulation to generate a NL description of the final state, and compare that NL description to the NL input data in generating a suitability metric. For instance, an embedding of the NL description of the final state can be compared to an embedding that is based on the NL description data (e.g., based on only the NL description data or based on the NL description data supplemented or modified as described herein).

At block 316, the system determines whether any of the action set(s), in a most recent iteration of block 314, are suitable. If so, the system proceeds to block 320 and causes real-world implementation of the most suitable action set (e.g., having the best suitability metric). In some implementations or situations, block 320 can include automatically causing real-world implementation. In some other implementations or situations, block 320 can include first prompting a user for affirmation of the action set, and only causing real-world implementation if affirmation is received in response. In yet other implementations or situations, block 320 can include transmitting data, that reflects the action set, to one or more computing device(s) for presentation to user(s) for implementation and/or for future implementation by the computing device(s).

If, at block 316, the system determines none of the actions in a most recent iteration of block 314 are suitable, the system proceeds to block 318. At block 318, the system selects an alternate request embedding technique and/or an alternate action model. The system then proceeds back to block 306 and performs another iteration of blocks 306, 308, 310 and, optionally, 312, 314, and 316 using the alternate request embedding technique and/or an alternate action model. This can continue until a suitable action set is determined or until other condition(s) are satisfied (e.g., a threshold number of iterations are performed and/or embedding technique and/or action model variations are exhausted).

The alternate request embedding technique and/or an alternate action model selected at each iteration of block 318 are unique relative to any that have been utilized in the current performance of method 300 for the instant NL input. In some implementations, the system can utilize heuristic(s) and/or a trained selection model in selecting likely next best embedding technique(s) and/or action model(s). For example, defined heuristics can indicate which embedding technique and action model to utilize initially, which to utilize next, which to utilize after that, etc. As another example, the system can process the NL input data (e.g., an embedding thereof) and/or an indication of the domain, using a trained selection model (e.g., one of the selection model(s) 156 of FIG. 1), to generate output that indicates probabilities for embedding techniques and/or action models. The system can select a next embedding technique and/or action model(s) to utilize based on the probabilities.

In some implementations, the system can additionally and/or alternatively utilize data from block 308 in determining whether to adjust the most recent embedding technique or to instead adjust most recent action model(s) being utilized. For example, if action model(s), utilized in the most recent iteration, indicate a threshold degree of confidence in the generated candidate action set, but it nonetheless was found to be unsuitable, this can indicate that the most recent request embedding is inaccurate, but the most recent action model(s) are likely the correct ones to utilize. In response, the system can choose an alternate embedding technique. On the other hand, if action model(s), utilized in the most recent iteration, indicate less than the threshold degree of confidence in the generated candidate action set, this can indicate that the most recent action model(s) are likely not the correct ones to utilize. In response, the system can choose alternate action model(s).

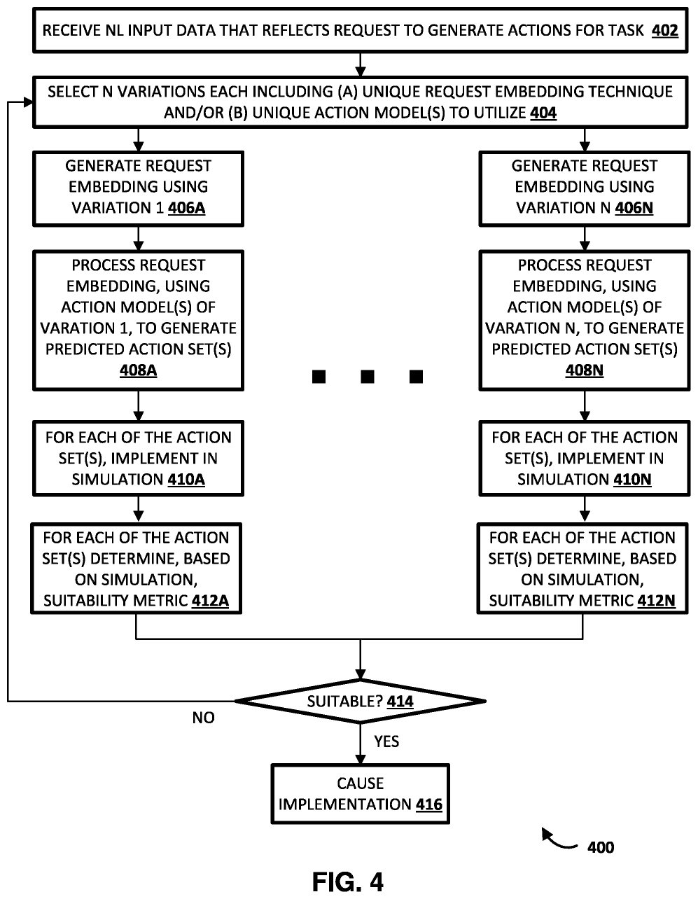

FIG. 4 is a flowchart illustrating another example method 400 for practicing selected aspects of the present disclosure, according to implementations disclosed herein. For convenience, the operations of the flow chart are described with reference to a system that performs the operations. This system may include various components of various computer systems, such as one or more components of neural arena system 120. Moreover, while operations of method 400 are shown in a particular order, this is not meant to be limiting. One or more operations may be reordered, omitted or added.

Initially, it is noted that method 400 of FIG. 4 includes many aspects in common with method 300 of FIG. 3. However, in method 400 multiple variations of request embedding technique, action model combinations are utilized, in parallel, in generating candidate action sets.

At block 402, the system receives NL input data that reflects a request to automatically generate actions for a task.

At block 404, the system selects N variations, where N is an integer greater than one. Each of the variations includes a unique request embedding technique and/or unique action model(s) to utilize. The request embedding technique and/or action model(s) are unique in that the combination of the two is not present in any other variation for the current iteration of block 404, or for prior iteration(s) of block 404 for the same request of block 402. As one example, the system can generate a first variation that includes a first embedding technique and a first action model, a second variation that includes a second embedding technique and a second action model, and a third variation that includes a third embedding technique and the first action model.

At block 406A, the system generates a request embedding using a first variation of the variations selected at a most recent iteration of block 404.

At block 408A, the system processes the request embedding, of block 406A, using action model(s) of the first variation, to generate predicted action set(s).

At block 410A, the system, for each of the action set(s), implement(s) the action set in simulation.

At block 412A, the system determines, for each of the action sets and based on simulation data from the simulation, a suitability metric for the action set.

Similarly, at block 406N, the system generates a request embedding using an Nth variation of the variations selected at a most recent iteration of block 404. Further, at block 408N, the system processes the request embedding, of block 406N, using action model(s) of the Nth variation, to generate predicted action set(s). Yet further, at block 410N, the system, for each of the action set(s), implement(s) the action set in simulation. Yet further, at block 412N, the system determines, for each of the action sets and based on simulation data from the simulation, a suitability metric for the action set.

As indicated by the horizontal ellipsis in FIG. 4, in implementations where there are more than two variations generated at an iteration of block 404, for each of those variations the system can similarly generate a request embedding and predicted action set(s) using that variation, implement each of the predicted action set(s) in simulation, and use corresponding simulated data in determining corresponding suitability metric(s) for the predicted action set(s).

At block 414, the system determines, based on the suitability metrics generated at blocks 412A-N, whether any of the candidate action sets is suitable. If not, the system proceeds back to block 404. If so, the system proceeds to block 416 and causes real-world implementation of the suitable candidate action set.

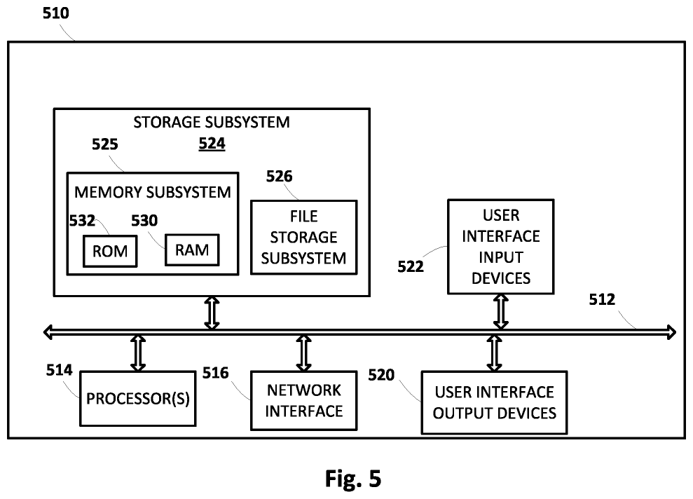

FIG. 5 is a block diagram of an example computing device 510 that may optionally be utilized to perform one or more aspects of techniques described herein. In some implementations, the client device 110, the neural arena system 120, and/or other component(s) can comprise one or more components of the example computing device 510.

Computing device 510 typically includes at least one processor 514 which communicates with a number of peripheral devices via bus subsystem 512. These peripheral devices may include a storage subsystem 524, including, for example, a memory subsystem 525 and a file storage subsystem 526, user interface output devices 520, user interface input devices 522, and a network interface subsystem 516. The input and output devices allow user interaction with computing device 510. Network interface subsystem 516 provides an interface to outside networks and is coupled to corresponding interface devices in other computing devices.

User interface input devices 522 may include a keyboard, pointing devices such as a mouse, trackball, touchpad, or graphics tablet, a scanner, a touch screen incorporated into the display, audio input devices such as voice recognition systems, microphones, and/or other types of input devices. In general, use of the term “input device” is intended to include all possible types of devices and ways to input information into computing device 510 or onto a communication network.

User interface output devices 520 may include a display subsystem, a printer, a fax machine, or non-visual displays such as audio output devices. The display subsystem may include a cathode ray tube (CRT), a flat-panel device such as a liquid crystal display (LCD), a projection device, or some other mechanism for creating a visible image. The display subsystem may also provide non-visual display such as via audio output devices. In general, use of the term “output device” is intended to include all possible types of devices and ways to output information from computing device 510 to the user or to another machine or computing device.

Storage subsystem 524 stores programming and data constructs that provide the functionality of some or all of the modules described herein. For example, the storage subsystem 524 may include the logic to perform selected aspects of the method 300 of FIG. 3, the method 400 of FIG. 4, and/or other method(s) described herein.

These software modules are generally executed by processor 514 alone or in combination with other processors. Memory 525 used in the storage subsystem 524 can include a number of memories including a main random access memory (RAM) 530 for storage of instructions and data during program execution and a read only memory (ROM) 532 in which fixed instructions are stored. A file storage subsystem 526 can provide persistent storage for program and data files, and may include a hard disk drive, a floppy disk drive along with associated removable media, a CD-ROM drive, an optical drive, or removable media cartridges. The modules implementing the functionality of certain implementations may be stored by file storage subsystem 526 in the storage subsystem 524, or in other machines accessible by the processor(s) 514.

Bus subsystem 512 provides a mechanism for letting the various components and subsystems of computing device 510 communicate with each other as intended. Although bus subsystem 512 is shown schematically as a single bus, alternative implementations of the bus subsystem may use multiple buses.

Computing device 510 can be of varying types including a workstation, server, computing cluster, blade server, server farm, or any other data processing system or computing device. Due to the ever-changing nature of computers and networks, the description of computing device 510 depicted in FIG. 5 is intended only as a specific example for purposes of illustrating some implementations. Many other configurations of computing device 510 are possible having more or fewer components than the computing device depicted in FIG. 5.

While several implementations have been described and illustrated herein, a variety of other means and/or structures for performing the function and/or obtaining the results and/or one or more of the advantages described herein may be utilized, and each of such variations and/or modifications is deemed to be within the scope of the implementations described herein. More generally, all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific implementations described herein. It is, therefore, to be understood that the foregoing implementations are presented by way of example only and that, within the scope of the appended claims and equivalents thereto, implementations may be practiced otherwise than as specifically described and claimed. Implementations of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

In some implementations, a method implemented by one or more processors is provided and includes receiving natural language input data that reflects a user request to automatically generate actions for performing a task in dependence on a corresponding state of a domain. The method further includes generating a request embedding based on processing the natural language input data. The method further includes performing a simulation, of the task, by implementing, in a simulated environment that reflects the corresponding state of the domain, a predicted action set generated based on processing the request embedding using one or more trained action models. The method further includes determining, based on the simulation, that the predicted action set is not suitable for performing the task. The method further includes, in response to determining that the predicted action set is not suitable for performing the task, generating an alternate predicted action set for performing the task. In some implementations, generating the alternate predicted action set includes: utilizing an alternate request embedding in generating the alternate predicted action set, and/or utilizing at least one alternate trained action model in generating the alternate predicted action set. The method further includes determining that the alternate predicted action set is suitable for performing the task and, in response to determining that the alternate predicted action set is suitable for performing the task, transmitting data to cause the alternate predicted action set to be implemented, in a real-world environment, to perform the task.

These and other implementations of the technology disclosed herein can optionally include one or more of the following features.

In some implementations, the method further includes generating the predicted action set based on processing the request embedding using the one or more trained action models. In some of those implementations, generating the predicted action set occurs prior to performing the simulation.

In some implementations, the method further includes generating the predicted action set based on processing the request embedding using the one or more trained action models. In some of those implementations, generating the predicted action set occurs during performing the simulation and is further based on processing, using the one or more trained action models, simulated state data generated during performing the simulation. The simulated state data that is processed can be dependent on the trained action model(s) that are utilized. For example, some trained action model(s) can be configured to process simulated state data that includes pixels from simulated image(s) from simulation and other trained action model(s) can be trained to process shape(s) and/or other feature(s) detected from simulated image(s) without processing the simulated image(s) themselves.

In some implementations, determining that the alternate predicted actions are suitable for performing the task includes: performing an additional simulation, of the task, by implementing the alternate predicted actions in the simulated environment; and determining, based on the additional simulation, that the alternate predicted actions are suitable for performing the task.

In some implementations, determining, based on the simulation, that the predicted actions are not suitable for performing the task, includes: processing simulation data, from the simulation using the predicted action, to generate natural language output that describes the processed simulation data; generating a metric based on comparing the natural language output to the natural language input data; and determining, based on the metric failing to satisfy a threshold, that the predicted actions are not suitable for performing the task. In some versions of those implementations, the natural language output is natural language text or a natural language embedding. In some additional and/or alternative versions of those implementations, the simulation data includes a final state, of the simulated environment, from the simulation using the predicted actions.

In some implementations, determining, based on the simulation, that the predicted actions are not suitable for performing the task, includes: processing simulation data, from the simulation using the predicted action, to determine whether one or more domain or task specific rules are violated and, in response to determining at least one of the one or more domain or task specific rules are violated: determining that the predicted actions are not suitable for performing the task. In some versions of those implementations, the method further includes determining a particular action, of the predicted actions, whose implementation in simulation resulted in a given one of the one or more domain or task specific rules being violated. In some of those versions, determining that the alternate predicted actions are suitable for performing the task includes determining that the alternate predicted actions lack the particular action.

In some implementations, determining, based on the simulation, that the predicted actions are not suitable for performing the task, includes: causing simulation data, from the simulation using the predicted action, to be rendered at a client device via which the user request was received; receiving user interface input, provided at the client device, responsive to causing the simulation data to be rendered at the client device; and determining, based on the user interface input, that the predicted actions are not suitable for performing the task. In some versions of those implementations, the simulation data includes a final state, of the simulated environment, from the simulation using the predicted actions. In some of those versions, the method further includes determining, based on the user interface input being directed to a particular feature of the final state, a particular action, of the predicted actions, whose implementation in simulation resulted in the particular feature. In those some versions, determining that the alternate predicted actions are suitable for performing the task includes determining that the alternate predicted actions lack the particular action.

In some implementations, generating the alternate predicted action set includes utilizing the at least one alternate trained action model and not using the one or more trained action models utilized in generating the predicted action set.

In some alternate request embedding implementations, generating the alternate predicted action set includes using the alternate request embedding in generating the alternate predicted action set.

In some alternate request embedding implementations: generating the request embedding includes generating a natural language embedding based on processing the natural language input data using a language model, and generating the request embedding based on the natural language embedding; and generating the alternate request embedding includes: generating alternate natural language input data by modifying and/or supplementing the natural language input data using one or more supplemental terms from a domain specific knowledge base for the task; generating an alternate natural language embedding based on processing the alternate natural language input data using a language model; and generating the alternate request embedding based on the alternate natural language embedding. In those implementations, the one or more supplemental terms are not utilized in generating the request embedding.

In some alternate request embedding implementations: generating the request embedding includes generating a natural language embedding based on processing the natural language input data using a language model, and generating the request embedding based on the natural language embedding; and generating the alternate request embedding includes: generating alternate natural language input data by modifying and/or supplementing the natural language input data using one or more supplemental terms from an external knowledge source that is not specific to the domain or to the task; generating an alternate natural language embedding based on processing the alternate natural language input data using a language model; and generating the alternate request embedding based on the alternate natural language embedding. In those implementations, the one or more supplemental terms are not utilized in generating the request embedding.

In some alternate request embedding implementations: generating the alternate request embedding includes causing a clarification prompt to be rendered at a client device via which the user request was received, receiving user feedback that is provided in response to the clarification prompt and via one or more user interface inputs at the client device, and generating the alternate request embedding based on processing the user feedback. In those implementations, the user feedback is not utilized in generating the request embedding.

In some alternate request embedding implementations generating the alternate request embedding includes generating a context embedding based on processing context data, and generating the alternate request embedding further based on the context embedding. In those implementations, the context data is not utilized in generating the request embedding.

In some alternate request embedding implementations generating the request embedding includes generating the request embedding based on processing the natural language input data and processing first context data, without processing second context data; and generating the alternate request embedding includes: generating the request embedding based on processing the natural language input data and processing the second context data, and without processing the first context data. In some versions of those implementations, the first context data represents a current state of the domain at a first level of abstraction and the second context data represents the current state of the domain at a second level of abstraction. In some of those versions, the current state of the domain includes an image being rendered and the first level abstraction is a pixel-level abstraction and the second level of abstraction is a shape-level abstraction.

In some implementations, generating the alternate predicted action set includes processing the alternate request embedding, utilizing the at least one alternate trained action model, in generating the alternate predicted action set.

In some implementations, the method further includes determining, based on one or more probabilities, whether to utilize the alternate request embedding or to instead utilize the at least one alternate trained action model, in generating the alternate predicted action set. In some of those implementations, the one or more probabilities are for the predicted action set and are generated based on processing the request embedding using the one or more trained action models.

In some implementations, determining, based on the one or more probabilities, whether to utilize the alternate request embedding or to instead utilize the at least one alternate trained action model, in generating the alternate predicted action set, includes: determining to utilize the alternate request embedding in response to the one or more probabilities satisfying one or more thresholds that indicate at least a threshold degree of confidence in the predicted action set. In some of those implementations, determining, based on the one or more probabilities, whether to utilize the alternate request embedding or to instead utilize the at least one alternate trained action model, in generating the alternate predicted action set, includes: determining to utilize the alternate trained action model in response to the one or more probabilities failing to satisfy one or more thresholds that indicate at least a threshold degree of confidence in the predicted action set.

In some implementations, the predicted action set includes a first group of actions in a first sequence, and the alternate action set includes the first group of the actions in a second sequence or a second group of the actions in a third sequence.

In some implementations, transmitting the data to cause the alternate predicted action set to be implemented, in the real-world environment, to perform the task, includes transmitting the data to cause the alternate predicted action set to be automatically implemented in response to the user request, and automatically implemented without requiring any further user input after providing the user request.

In some implementations, a method implemented by one or more processors is provided and includes receiving natural language input that includes a request to automatically generate actions for performing a task in dependence on a corresponding state of a domain. The method further includes generating a first request embedding based on performing first processing. The first processing is based on at least the natural language input. The method further includes processing the first request embedding, using at least one trained action model, to generate first predicted actions for performing the task. The method further includes performing a first simulation, of the task, that implements the first predicted actions in a simulated environment that reflects the corresponding state of the domain. The method further includes determining, based on the first simulation, a first suitability metric for the first predicted actions. The method further includes generating, based on performing second processing, a second request embedding that differs from the first request embedding. The second processing is based on at least the natural language input. The method further includes processing the second request embedding, using the at least one trained action model or at least one alternate trained action model, to generate second predicted actions for performing the task. The method further includes performing a second simulation, of the task, that implements the second predicted actions in the simulated environment that reflects the corresponding state of the domain. The method further includes determining, based on the second simulation, a second suitability metric for the second actions. The method further includes determining, based on comparing the first suitability metric and the second suitability metric, to implement the second actions in lieu of the first actions. The method further includes, in response to determining to implement the second actions, transmitting data to cause the second actions to be implemented, in a real-world environment, to perform the task.

These and other implementations of the technology disclosed herein can optionally include one or more of the following features.

In some implementations, the method further includes determining the first suitability metric fails to satisfy a threshold. In some of those implementations, one or more of the following are performed subsequent to and in response to determining the first suitability metric fails to satisfy the threshold: generating the second request embedding; processing the second request embedding to generate the second predicted actions; performing the second simulation; or determining the second suitability metric.

In some implementations, one or more of the following are performed prior to or in parallel with determining the first suitability metric: generating the second request embedding; processing the second request embedding to generate the second predicted actions; performing the second simulation; and/or determining the second suitability metric.

What is claimed is:

1. A method implemented by one or more processors, the method comprising:
receiving natural language input data that reflects a user request to automatically generate actions for performing a task in dependence on a corresponding state of a domain;
generating a request embedding based on processing the natural language input data;
performing a simulation, of the task, by implementing, in a simulated environment that reflects the corresponding state of the domain, a predicted action set generated based on processing the request embedding using one or more trained action models;
determining, based on the simulation, that the predicted action set is not suitable for performing the task;
in response to determining that the predicted action set is not suitable for performing the task:
generating an alternate predicted action set for performing the task, wherein generating the alternate predicted action set comprises:
utilizing an alternate request embedding in generating the alternate predicted action set, and/or
utilizing at least one alternate trained action model in generating the alternate predicted action set;
determining that the alternate predicted action set is suitable for performing the task;
in response to determining that the alternate predicted action set is suitable for performing the task:
transmitting data to cause the alternate predicted action set to be implemented, in a real-world environment, to perform the task.

2. The method of claim 1, further comprising:
generating the predicted action set based on processing the request embedding using the one or more trained action models,
wherein generating the predicted action set occurs prior to performing the simulation.

3. The method of claim 1, further comprising:
generating the predicted action set based on processing the request embedding using the one or more trained action models,
wherein generating the predicted action set occurs during performing the simulation and is further based on processing, using the one or more trained action models, simulated state data generated during performing the simulation.

4. The method of claim 1, wherein determining that the alternate predicted actions are suitable for performing the task comprises:
performing an additional simulation, of the task, by implementing the alternate predicted actions in the simulated environment; and
determining, based on the additional simulation, that the alternate predicted actions are suitable for performing the task.

5. The method of claim 1, wherein determining, based on the simulation, that the predicted actions are not suitable for performing the task, comprises:
processing simulation data, from the simulation using the predicted action, to generate natural language output that describes the processed simulation data;
generating a metric based on comparing the natural language output to the natural language input data; and
determining, based on the metric failing to satisfy a threshold, that the predicted actions are not suitable for performing the task.

6. The method of claim 5, wherein the simulation data comprises a final state, of the simulated environment, from the simulation using the predicted actions.

7. The method of claim 1, wherein determining, based on the simulation, that the predicted actions are not suitable for performing the task, comprises:
processing simulation data, from the simulation using the predicted action, to determine whether one or more domain or task specific rules are violated;
in response to determining at least one of the one or more domain or task specific rules are violated:
determining that the predicted actions are not suitable for performing the task.

8. The method of claim 1, wherein determining, based on the simulation, that the predicted actions are not suitable for performing the task, comprises:
causing simulation data, from the simulation using the predicted action, to be rendered at a client device via which the user request was received;
receiving user interface input, provided at the client device, responsive to causing the simulation data to be rendered at the client device;
determining, based on the user interface input, that the predicted actions are not suitable for performing the task.

9. The method of claim 8, wherein the simulation data comprises a final state, of the simulated environment, from the simulation using the predicted actions.

10. The method of claim 9, further comprising:
determining, based on the user interface input being directed to a particular feature of the final state, a particular action, of the predicted actions, whose implementation in simulation resulted in the particular feature;
wherein determining that the alternate predicted actions are suitable for performing the task comprises determining that the alternate predicted actions lack the particular action.

11. The method of claim 1, wherein generating the alternate predicted action set comprises using the alternate request embedding in generating the alternate predicted action set.

12. The method of claim 11,
wherein generating the request embedding comprises:
generating a natural language embedding based on processing the natural language input data using a language model; and
generating the request embedding based on the natural language embedding;
wherein generating the alternate request embedding comprises:
generating alternate natural language input data by modifying and/or supplementing the natural language input data using one or more supplemental terms from a domain specific knowledge base for the task;
generating an alternate natural language embedding based on processing the alternate natural language input data using a language model; and
generating the alternate request embedding based on the alternate natural language embedding;
wherein the one or more supplemental terms are not utilized in generating the request embedding.

13. The method of claim 11,
wherein generating the request embedding comprises:
generating a natural language embedding based on processing the natural language input data using a language model; and
generating the request embedding based on the natural language embedding;
wherein generating the alternate request embedding comprises:
generating alternate natural language input data by modifying and/or supplementing the natural language input data using one or more supplemental terms from an external knowledge source that is not specific to the domain or to the task;
generating an alternate natural language embedding based on processing the alternate natural language input data using a language model; and
generating the alternate request embedding based on the alternate natural language embedding; and
wherein the one or more supplemental terms are not utilized in generating the request embedding.

14. The method of claim 11, wherein generating the alternate request embedding comprises:
causing a clarification prompt to be rendered at a client device via which the user request was received;
receiving user feedback that is provided in response to the clarification prompt and via one or more user interface inputs at the client device; and
generating the alternate request embedding based on processing the user feedback; and
wherein the user feedback is not utilized in generating the request embedding.

15. The method of claim 11, wherein generating the alternate request embedding comprises:
generating a context embedding based on processing context data; and
generating the alternate request embedding further based on the context embedding;
wherein the context data is not utilized in generating the request embedding.

16. The method of claim 11,
wherein generating the request embedding comprises:
generating the request embedding based on processing the natural language input data and processing first context data, without processing second context data; and
wherein generating the alternate request embedding comprises:
generating the request embedding based on processing the natural language input data and processing the second context data, and without processing the first context data.

17. The method of claim 16, wherein the first context data represents a current state of the domain at a first level of abstraction and the second context data represents the current state of the domain at a second level of abstraction.

18. The method of claim 1, further comprising:
determining, based on one or more probabilities, whether to utilize the alternate request embedding or to instead utilize the at least one alternate trained action model, in generating the alternate predicted action set,
wherein the one or more probabilities are for the predicted action set and are generated based on processing the request embedding using the one or more trained action models.

19. The method of claim 1, wherein transmitting the data to cause the alternate predicted action set to be implemented, in the real-world environment, to perform the task, comprises:
transmitting the data to cause the alternate predicted action automatically implemented in response to the user request, and automatically implemented without requiring any further user input after providing the user request.

20. A method implemented by one or more processors, the method comprising:
receiving natural language input that includes a request to automatically generate actions for performing a task in dependence on a corresponding state of a domain;
generating a first request embedding based on performing first processing, the first processing being based on at least the natural language input;
processing the first request embedding, using at least one trained action model, to generate first predicted actions for performing the task;
performing a first simulation, of the task, that implements the first predicted actions in a simulated environment that reflects the corresponding state of the domain;
determining, based on the first simulation, a first suitability metric for the first predicted actions;
generating, based on performing second processing, a second request embedding that differs from the first request embedding, the second processing being based on at least the natural language input;
processing the second request embedding, using the at least one trained action model or at least one alternate trained action model, to generate second predicted actions for performing the task;
performing a second simulation, of the task, that implements the second predicted actions in the simulated environment that reflects the corresponding state of the domain;
determining, based on the second simulation, a second suitability metric for the second actions;
determining, based on comparing the first suitability metric and the second suitability metric, to implement the second actions in lieu of the first actions; and
in response to determining to implement the second actions:
transmitting data to cause the second actions to be implemented, in a real-world environment, to perform the task.
